(19) United States
(12) Patent Application Publication
(10) Pub. No.: US 2005/0077959 A1
(43) Pub. Date: Apr. 14, 2005

(54) Gain control circuit

(76) Inventor: Koji Hika, Kariya-shi (JP)

Correspondence Address: Morgan & Finnegan, L.L.P., 3 World Financial Center, New York, NY, 10281-2101, US

(21) Appl. No.: 10/958,433

(22) Filed: Oct. 5, 2004

(30) Foreign Application Priority Data
Oct. 6, 2003 (JP) 2003-347685

(51) Int. Cl. H03G 3/20

(52) U.S. Cl. 330/129

(57) ABSTRACT

It is an object of the present invention to provide a gain control circuit capable of reducing convergence time needed to stabilize the output level changing due to the fluctuations of an input level, maintaining the convergence time constant even if a signal with a different level is inputted to a variable gain amplifier and easily modifying a setting value even if the gain characteristic of the variable gain amplifier changes. A gain control unit normally adjusts the gain of a VGA according to a difference computed by a computation unit. If an input signal with a high level is inputted to the VGA immediately after receiving a packet and the output level of the VGA exceeds the threshold value of a step-down unit, the gain of the VGA can be forced to reduce by a prescribed value.

### BACKGROUND OF THE INVENTION

1. Field of the Invention

The present invention relates to a gain control circuit for controlling the gain of a variable gain amplifier in order to maintain the output level of the variable gain amplifier constant.

2. Description of the Related Art

FIG. 1A shows the configuration of a conventional gain control circuit.

As shown in FIG. 1A, a gain control circuit 60 comprises a detection unit 62 for detecting the level of the output signal (gain adjusted signal) of a variable gain amplifier 61 for amplifying an input signal, a computation unit 63 for computing a difference between the level detected by the detection unit 62 and a reference level, a multiplication unit 64 for multiplying the difference computed by the computation unit 63 by a specific value (scale) and an integration unit 65 for integrating the value multiplied by the multiplication unit 64 and outputting a control signal based on the integrated value to the variable gain amplifier 61 (for example, see Non-Patent Reference 1)

This gain control circuit 60 outputs a control signal such that the difference between a level detected by the detection unit 62 and the reference level may become zero to the variable gain amplifier 61 to control the gain of the variable gain amplifier 61.

Thus, the output level of the variable gain amplifier 61 can be converged on the reference level, and accordingly, the output level of the variable gain amplifier 61 can be stabilized at a desired level.

FIG. 1B shows another configuration of the conventional gain control circuit.

As shown in FIG. 1B, a gain control circuit 66 comprises a detection unit 68 with the gain characteristic of an exponential function, for detecting the level of the output signal (y(n)=A(n)×(n)) of a variable gain amplifier 67 for amplifying an input signal (×(n)), a conversion unit 69 for applying logarithm (log) conversion to the level detected by the detection unit 68, a computation unit 70 computing a difference between the log value converted by the conversion unit 69 and a reference value (log(R)), a multiplication unit 71 for multiplying the difference computed by the computation unit 70 by a specific value (α), an integration unit 72 for integrating the value multiplied by the multiplication unit 71 and a conversion unit 73 applying exponential (exp) conversion to the value integrated by the integration unit 72 and outputting a control value based on the converted value to the variable gain amplifier 67.

This gain control circuit 66 outputs a control signal such that the difference between the value inverted by the conversion unit 69 and the reference value may become zero to the variable gain amplifier 67 to control the gain of the variable gain amplifier 67.

Thus, the output level of the variable gain amplifier 67 can be converged on the reference level, and accordingly, the output level of the variable gain amplifier 67 can be stabilized at a desired level.

As disclosed in Patent Reference 1, a gain control circuit for outputting a control signal such that the output level of a variable gain amplifier and a reference level may become zero while changing the gain change rate of the variable gain amplifier according to the gain of the variable gain amplifier (electronic volume unit 8) to control the gain of the variable gain amplifier is also known (for example, see Patent Reference 1).
Non-Patent Reference: Isaac Martinez G, [online], <URL: http://www.eecg.toronto.edu/˜kphang/papers/2001/martin_AGC.pdf
   Patent Reference 1: Japanese Patent Application No. 9-93063 (Pages 3-5 and FIG. 1)

However, in the gain control circuit 60 shown in FIG. 1A, the gain control circuit 66 shown in FIG. 1B and the gain control circuit disclosed in Patent Reference 1, time needed to stably converge the output level of a variable gain amplifier on a desired level after the fluctuations of an input level is long, which is a problem. For example, although in Patent Reference 1, the gain change rate is changed, the convergence time becomes long since there is only one control means.

In these gain control circuits, time needed to stably converge the output level of a variable gain amplifier on a desired level varies with the level of a signal inputted to the variable gain amplifier, which is another problem.

In these gain control circuits, if the gain characteristic of a variable gain amplifier changes when exchanging the variable gain amplifier or the like, the modification work of a setting value, such as a reference level or the like, becomes troublesome, which is another problem.

### SUMMARY OF THE INVENTION

It is an object of the present invention to provide a gain control circuit whose convergence time can be reduced and can be maintained constant and whose setting value can be easily modified.

In order to solve the above-mentioned problems, the present invention adopts the following configuration.

Specifically, the gain control circuit of the present invention comprises a detection unit for detecting the output level of a variable gain amplifier for amplifying and outputting an input signal, a first gain change unit for adjusting the gain of the variable gain amplifier according to the difference between the output level detected by the detection unit and a pre-determined reference level, and a second gain change unit for forcing to reduce the gain of the variable gain amplifier by a prescribed value when the output level detected by the detection unit exceeds a prescribed first threshold value.

According to the above-mentioned gain control circuit, normally (that is, when the output level of the variable gain amplifier does not exceed the first threshold value), the first gain change unit can control the gain of the variable gain amplifier to maintain the output level of the variable gain amplifier at a prescribed value corresponding to the reference level. Furthermore, when the output level of the variable gain amplifier exceeds the first threshold value, accompanying the fluctuations of an input signal or the like, the second gain change unit can force to reduce the gain of the variable gain amplifier by a prescribed value. Thus, the output level of the variable gain amplifier can be adjusted to the first threshold value or less in a short time. Specifically, the output level of the variable gain amplifier can be brought close to a prescribed value corresponding to the reference level in a short time. Since time needed to converge the output level of the variable gain amplifier on the prescribed value to be maintained from the first threshold value is almost constant, convergence time against the fluctuations of the input level or the like becomes almost constant.

Alternatively, the second gain change unit of the gain control circuit can stepwise reduce the gain of the variable gain amplifier at prescribed time intervals until the output level detected by the detection unit decreases below the first threshold value.

As described above, by properly setting the prescribed time, the output level of the variable gain amplifier can be prevented from rapidly decreasing by reducing the gain too much in a short time.

Alternatively, the gain control circuit can individually set each amount of decrease when stepwise reducing the gain of the variable gain amplifier.

Thus, the gain change pattern of the variable gain amplifier can be arbitrarily set.

Alternatively, the gain control circuit can further comprise a conversion unit for applying log conversion to the output level detected by the detection unit, and the first gain change unit can adjust the gain of the variable gain amplifier according to the difference between the output level converted by the conversion unit and a predetermined reference level.

Alternatively, the gain control circuit can arbitrarily set the gain change pattern of the variable gain amplifier by modifying each amount of reduction and the times of reduction when stepwise reducing the gain of the variable gain amplifier.

Alternatively, the gain control circuit can further comprise a pre-amplifier immediately before the variable gain amplifier and a switch control unit for stopping the pre-amplifier when the input level of the variable gain amplifier exceeds the prescribed second threshold value. In this case, when the output level detected by the detection unit exceeds the first threshold value when the pre-amplifier stops, the gain of the variable gain amplifier can be forced to reduce by a prescribed value.

Alternatively, the gain control circuit can further comprise a pre-amplifier immediately before the variable gain amplifier and a switch control unit for stopping the pre-amplifier when the input level of the variable gain amplifier exceeds the prescribed second threshold value. In this case, the second gain change unit can adjust the gain of the variable gain amplifier so as to compensate for gain decrease due to the stoppage of the pre-amplifier.

Thus, even when stopping the pre-amplifier, the output level of the variable gain amplifier can be prevented from rapidly decreasing.

Alternatively, the gain control circuit can further comprise a pre-amplifier immediately before the variable gain amplifier and a switch control unit for stopping the pre-amplifier when the input level of the variable gain amplifier exceeds the prescribed second threshold value. In this case, the second gain-variable unit cannot force to reduce the gain of the variable gain amplifier before a prescribed time elapses after the switch control unit stops the pre-amplifier.

Thus, for example, if the pre-amplifier is stopped when stepwise reducing the gain of the variable gain amplifier, the output level of the variable gain amplifier can be prevented from decreasing more than required.

The amplification device of the present invention can also comprise a variable gain amplifier for amplifying an input signal and outputting, a detection unit for detecting the output level of the variable gain amplifier, a first gain change unit for adjusting the gain of the variable gain amplifier according to the difference between the output level detected by the detection unit and a predetermined reference level, and a second gain change unit for forcing to reduce the gain of the variable gain amplifier by a prescribed value when the output level detected by the detection unit exceeds the first threshold value.

### BRIEF DESCRIPTION OF THE DRAWINGS

FIG. 1A shows one typical configuration of the conventional gain control circuit;

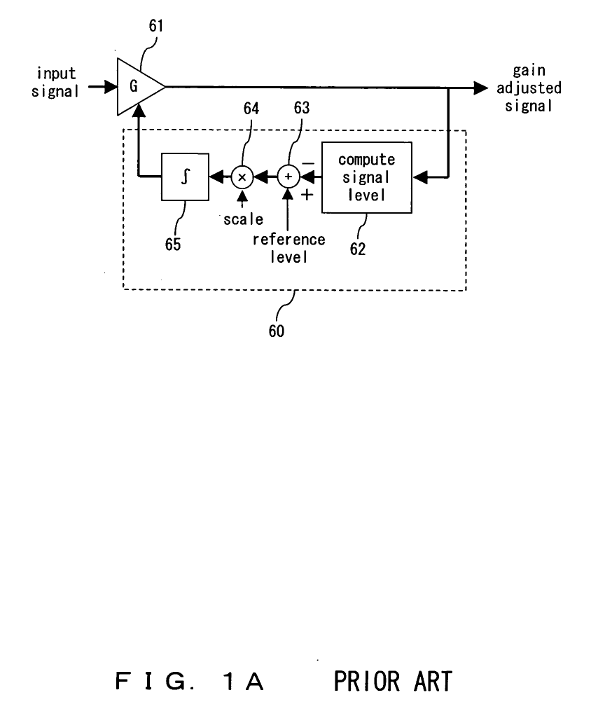

FIG. 1B shows another typical configuration of the conventional gain control circuit;

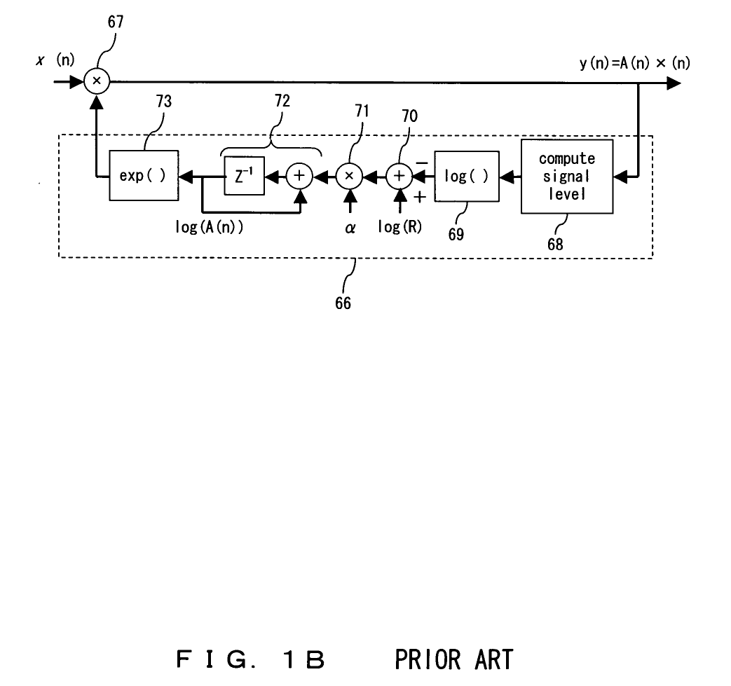

FIG. 2 shows one typical gain control circuit in the preferred embodiment of the present invention;

FIG. 3 shows the relationship between the output level of a variable gain amplifier (VGA) and the threshold value/gain control signal of a Step-down unit;

FIG. 4 shows the relationship between the output signal of an RF unit and a gain control signal;

FIG. 5 shows the relationship between the gain of the entire RF unit and a gain control signal;

FIG. 6A shows the relationship between a gain control signal and time; and

FIG. 6B shows the relationship between the gain of the entire RF unit and a gain control signal.

### DESCRIPTION OF THE PREFERRED EMBODIMENTS

The preferred embodiments of the present invention are described below with reference to the drawings.

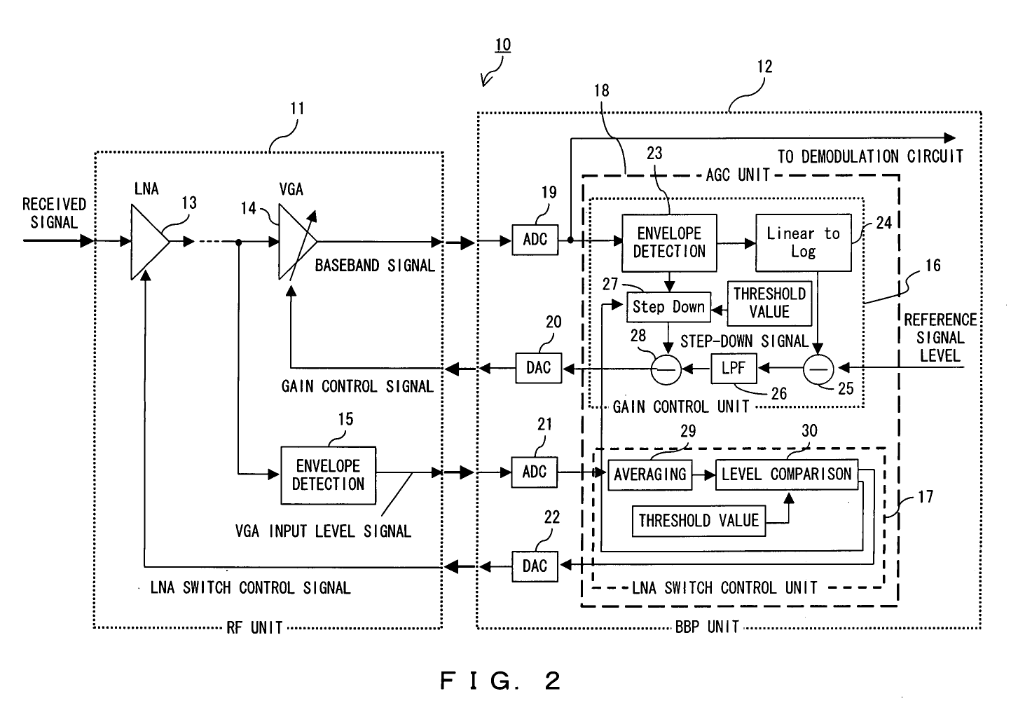

FIG. 2 shows one typical gain control circuit in the preferred embodiment of the present invention.

The amplification device 10 shown in FIG. 2 is provided before the receiving unit of a wireless local area network (LAN) device. The amplification device 10 comprises a radio frequency (RF) unit 11 and a baseband processor (BBP) unit 12 (gain control circuit). The amplification device 10 converts received signals into baseband signals and outputs them to a demodulation circuit.

The RF unit 11 comprises a low noise amplifier (LNA) 13 (pre-amplifier) for amplifying received signals, a VGA (Variable Gain Amplifier) 14 (variable gain amplifier) for stabilizing the level (amplitude) or a signal amplified by the LNA 13 at a desired level and an envelope detection unit 15 for outputting a VGA input level signal corresponding to the level to the BBP unit 12. The RF unit 11 adjusts the output level of the RF unit 11 by the LNA 13 and the VGA 14. As long as the envelope detection unit 15 can detect the input level of the VGA 14, its detection method is not limited to envelope detection. A received signal is converted into a baseband signal by a mixer provided for the RF unit 11, which is not shown in FIG. 2.

The BBP unit 12 comprises an AGC unit 18 composed of a gain control unit 16 for controlling the gain of the VGA 14 by outputting a gain control signal to the VGA 14, and a LNA switch control unit 17 for determining whether to stop the LNA 13 by outputting an LNA switch control signal to the LNA 13, an analog-to-digital converter (ADC) 19 for converting a baseband signal to be outputted from the RF unit 11, from analog to digital and outputting the converted digital baseband signal to a gain control unit 16 and also outputting the signal to a demodulation circuit, a digital-to-analog converter (DAC) 20 for converting a signal outputted from the gain control unit 16, from digital to analog and outputting the converted analog signal to the VGA 14, an ADC 21 for converting a VGA input level signal outputted from the RF unit 11, from analog to digital and outputting the converted digital signal to the LNA switch control unit 17, and a DAC 22 for converting a signal outputted from the LNA switch control unit 17, from digital to analog and outputting the converted analog signal to the LNA 13 as an LNA switch control signal. The BBP unit 12 stabilizes the level of a baseband signal at a desired level.

The gain control unit 16 comprises an envelope detection unit 23 (detection unit) for detecting the level or a signal outputted from the ADC 19, a linear-to-log unit 24 (conversion unit) for converting the level detected by the envelope detection unit 23 into a log value by table conversion or the like, a computation unit 25 for computing the difference between the level converted by the linear-to-log unit 24 and a predetermined reference level (reference level) and a low pass filter (LPF) 26 to which the difference computed by the computation unit 25 is inputted. Furthermore, the gain control unit 16 comprises a step-down unit 27 for outputting a step offset value for forcing to reduce the gain of the VGA 14 by a prescribed value when the level detected by the envelope detection unit 23 exceeds a predetermined threshold value (the first threshold value), and a computation unit 28 for outputting a value obtained by subtracting the step offset value of the step-down unit 27 from the output value of the LPF 26, to the DAC 20. If the envelope detection unit 23 can detect the output level of the VGA 14, its detection method is not limited to the envelope detection.

The LNA switch control unit 17 comprises an averaging unit 29 for averaging a signal outputted from the ADC 21, and a level comparison unit 30 for outputting a signal for stopping the LNA 13, to the DAC 22 when the value averaged by the averaging unit 29 exceeds a threshold (the second threshold value).

The first gain change unit comprises at least the computation unit 25, and the second gain change unit comprises at least the step-down unit 27 and the computation unit 28.

Next, the operation of the AGC unit 18 is described.

The AGC unit 18 controls both the on/off switch of the LNA 13 and the gain of the VGA 14 so that the difference between the log level converted by the linear-to-log unit 24 and the reference signal level may become zero, and maintains the gain of the VGA 14 in proper timing after the difference becomes zero. The gain control unit 16 normally (that is, when the output level of the VGA 14 does not exceed the threshold value of the step-down unit 27) adjusts the gain of the VGA 14 according to the difference computed by the computation unit 25. However, for example, when a received level rapidly increases immediately after receiving a packet or the like and the output level of the VGA 14 exceeds the threshold value of the step-down unit 27, the gain control unit 16 forces to reduce the gain of the VGA 14 by a prescribed value.

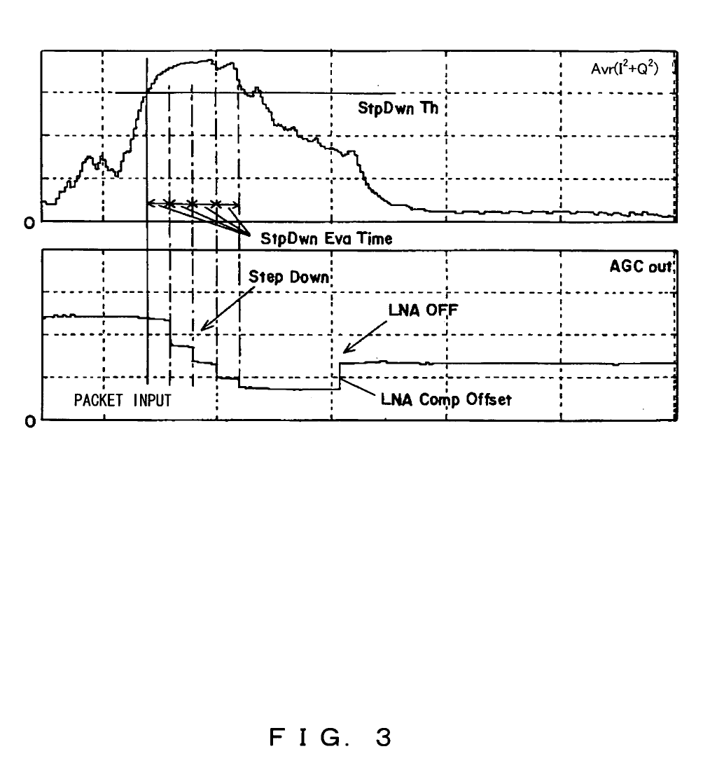

FIG. 3 shows the relationship between the output level of the VGA 14 and the threshold value/gain control signal of the step-down unit 27. The vertical and horizontal axes of the graph shown in the upper section of FIG. 3 indicate the output level of the VGA 14 (Avr(I²+Q²)) and time, respectively. The StepDwn_Th of the graph shown in the upper section of FIG. 3 indicates the threshold value of the step-down unit 27. The vertical and horizontal axes of the graph shown in the lower section of FIG. 3 indicate a gain control signal (AGC_out) and time, respectively. The respective time on the horizontal axes of the graphs shown in the upper and lower sections coincide with each other.

The envelope detection unit 23, for example, computes a plurality of I²+Q², based on the I component of an inputted baseband signal (in-phase component) and its Q component (quadrature phase component), designates the average value of the plurality of I²+Q² as the output level of the VGA 14, and outputs it to the linear-to-log unit 24 and the step-down unit 27.

The step-down unit 27 compares a value outputted from the envelope detection unit 23 (Avr(I²+Q²)) with the threshold value (StpDwn_Th), as shown in the upper graph of FIG. 3. Then, the step-down unit 27 computes what ratio the value outputted from the envelope detection unit 23 exceeds the threshold value during the period at specific intervals (StpDwn_Eva_Time), and if the ratio exceeds a rated value, it performs a step-down process. Specifically, for example, if the output value of the envelope detection unit 23 exceeds the threshold value in eight samples out of ten samples when one StpDwn_Eva_Time is divided into ten samples, the step-down unit 27 performs a step-down process. In this case, the number of samples of the StpDwn_Eva_Time and the rated value can be set by externally modifying a parameter or the like.

As described above, by performing a step-down process at specific intervals, the output level of the VGA 14 can be prevented from rapidly decreasing by reducing the gain too much in a short time.

The maximum times of the step-down process can also be set by externally modifying a parameter or the like. For example, if the maximum times of the step-down process are set to five, the process is sequentially executed as step 1, step 2, . . . and step 5. The upper graph of FIG. 3 shows a case where the maximum times of the step-down process is five and the output value of the envelope detection unit 23 becomes below the threshold value in the fourth step-down process. The lower graph of FIG. 3 shows that the larger the gain control signal, the larger the gain of the VGA 14, and that the gain of the VGA 14 is stepwise reduced for each StpDwn_Eva_Time, specifically, four times for each StpDwn_Eva_Time.

The step-offset value (a prescribed value by which the gain of the VGA 14 is forced to reduce) of the step-down process can also be set by externally modifying a parameter or the like. Specifically, for example, the step offset value of each step-down process shown in the lower graph of FIG. 3 can be set to “10”, “8”, “6”, “4” and “2” for the offset values of steps 1, 2, 3, 4 and 5, respectively. The respective step offset values of all step-down processes can also be set to the same.

As described above, by modifying the offset value of each step-down process, the gain change pattern of the VGA 14 can be arbitrarily set. Specifically, for example, by setting the step offset value so as to sequentially decrease, the gain characteristic curve of the VGA 14 can be convex downward. By setting the step offset value so as to sequentially increase, the gain characteristic curve of the VGA 14 can be convex upward.

When switching the LNA 13 on/off, in order to suppress the rapid change of the output level of the VGA 14 due to the on/off switch of the LNA 13, the step-down unit 27 outputs an LNA switch compensation offset value for compensating for the change, to the computation unit 28. Specifically, for example, as shown in the lower graph of FIG. 3, when the LNA 13 is switched from on (initial state) to off, the amplitude or a signal inputted to the VGA 14 rapidly decreases. Therefore, in order to compensate for this decrease, the step-down unit 27 increases the gain of the VGA 14 by adding an LNA switch compensation offset value, LNA_Comp_Offset and controls so as to suppress the fluctuations of the amplitude of an output signal as much as possible.

Thus, the output level of the VGA 14 is prevented from rapidly decreasing when the LNA 13 is stopped.

Next, the operation of the AGC unit 18 after the LNA 13 is stopped is described.

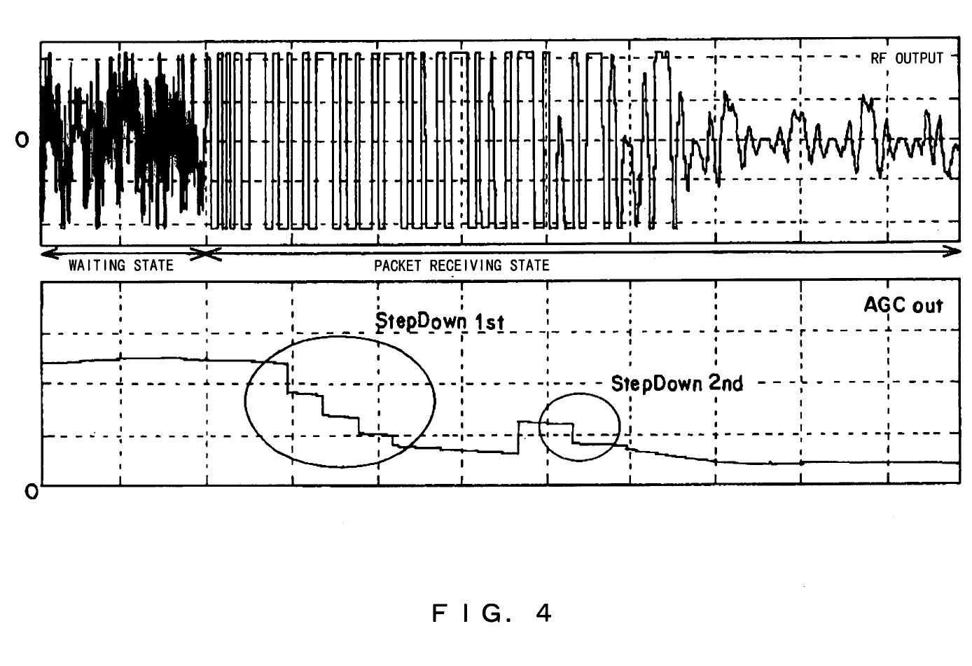

FIG. 4 shows the relationship between the output signal of the RF unit 11 and a gain control signal. The vertical and horizontal axes of the graph shown in the upper section of FIG. 4 indicate the output signal (RF output) of the RF unit 11 and time, respectively. The vertical and horizontal axes of the graph shown in the lower section of FIG. 4 indicate the level (AGC_out) of a gain control signal and time, respectively. The respective time on the horizontal axes of the graphs shown in the upper and lower sections of FIG. 4 coincide with each other. Up to the second scales from the left end of the horizontal axis of the upper graph shown in FIG. 4 show a state of waiting for an incoming signal, and scales after that show a state of receiving a packet.

If the output level exceeds the threshold value even after the LNA 13 is stopped, the step-down unit 27 performs the step-down process again. In the following description, these step-down processes after and before the stoppage of the LNA 13 are called StepDown2nd and StepDown1st, respectively.

Whether to perform this StepDown2nd is determined in the same way as StepDown1st. Specifically, what ratio the value outputted from the envelope detection unit 23 exceeds the threshold value during the period at specific intervals is computed, and if the ratio exceeds a rated value, the step-down process is performed. StepDown2nd differs from StepDown1st in that in StepDown2nd, a state of starting the step-down process can be set.

Specifically, in StepDown2nd, there is no need to reduce the gain of the VGA 14 as much as in StepDown1st. For example, if the offset values of StepDown1st shown in the lower graph of FIG. 4 are 10, 8, 6 and 4, as the step offset value of StepDown2nd, 10 is too much, and if 6 is sufficient, the step offset values of StepDown2nd are set to 6 and 4. The threshold value of StepDown2nd can be the same as or different from that of StepDown1st.

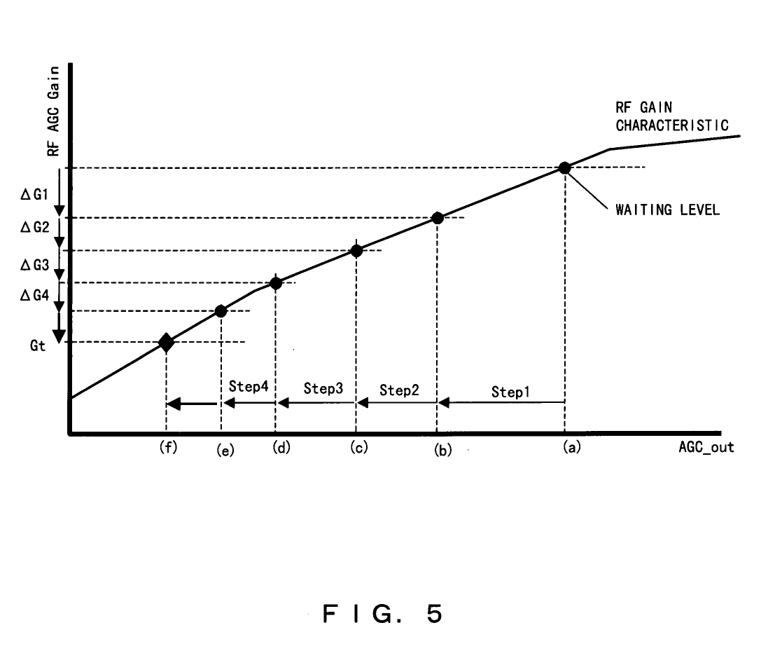

FIG. 5 shows the relationship between the gain of the entire RF unit (the total gain of the respective gains of the LNA 13 and VGA 14) and a gain control signal. The vertical and horizontal axes of the graph shown in FIG. 5 indicate the gain (RF AGC Gain) of the entire RF unit and a gain control signal (AGC_out), respectively, and the graph shows the gain characteristic of the RF unit 11. ΔG1 through ΔG4 indicate the respective amount of change of the gain of the RF unit 11 against the step-down process (Step 1 through Step 4), and Gt indicates the gain of the RF unit 11 needed to realize the target amplitude level of the baseband signal.

As shown in FIG. 5, in the waiting state (initial state), the RF unit 11 is amplifying the internal noise of a circuit, such as the wireless LAN device or the like, and in such a state, the gain of the entire RF unit 11 is high (a waiting level shown in FIG. 5). When the wireless LAN device receives a packet and a step-down process is performed, the gain of the entire RF unit 11 stepwise decreases by a specific amount from the waiting level. For example, as shown in FIG. 5, when in step 1 the gain control signal decreases from (a) to (b), the gain of the entire RF unit 11 decreases by ΔG1. Then, when the step-down process is performed up to step 4 and all the step-down processes are completed, the gain is smoothly controlled up to gain Gt only through the route of the envelope detection unit 23, the linear-to-log unit 24, the computation unit 25 and the LPF 26.

As described above, normally, the gain of the VGA 14 is controlled by the computation unit 25, and the output level of the VGA 14 is maintained at a prescribed value corresponding to the reference signal level. Furthermore, if the output level of the VGA 14 exceeds the threshold value of the step-down unit 27 accompanying the fluctuations of an input level or the like, the step-down unit 27 and the computation unit 28 force to reduce the gain of the VGA 14 by a prescribed value. Thus, the output level of the VGA 14 can be reduced below the threshold value of the step-down unit 27 in a short time. In other words, the output level of the VGA 14 can be brought close to a prescribed value corresponding to the reference signal level in a short time. Since time needed to converge the output level of the VGA 14 on a prescribed value to be maintained from the threshold value of the step-down unit 27 is almost constant, convergence time against the fluctuations of an input level or the like also becomes almost constant. Since the offset value, the maximum times of the step-down process, the threshold value and the like can be set by externally modifying a parameter or the like, the modification of the gain characteristic of the RF unit 11 can be flexibly coped with.

### Other Preferred Embodiments

(1) In the above-mentioned preferred embodiment, the on/off switch of the LNA 13 is made after StepDown1st is completed. However, if the on/off switch of the LNA 13 is made during StepDown1st, the gain change due to the stoppage of the LA 13 can also be part of gain change due to StepDown1st.

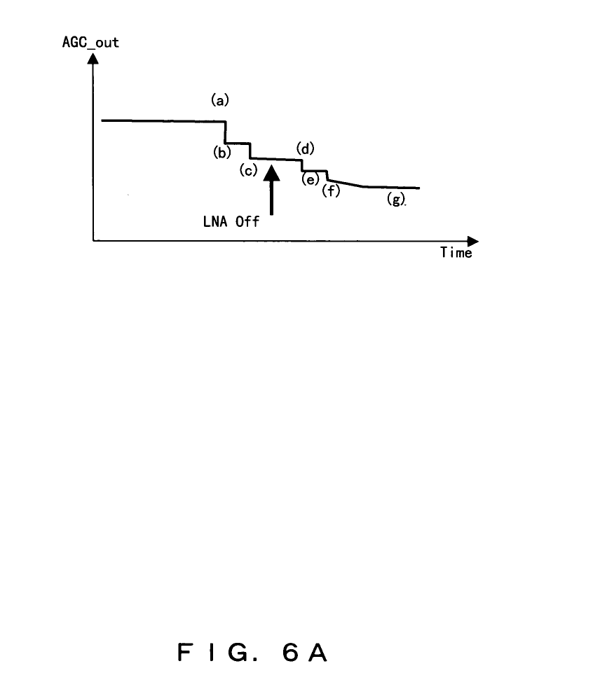

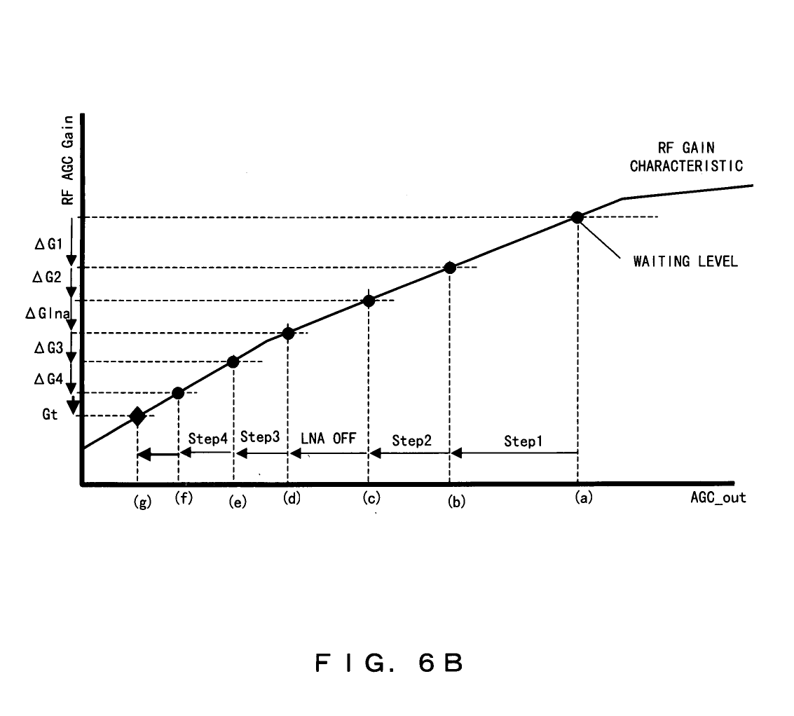

FIG. 6A shows the relationship between a gain control signal and time. The vertical and horizontal axes of the graph shown in FIG. 6A indicate a gain control signal (AGC_out) and time, respectively. FIG. 6B shows the relationship between the gain of the entire RF unit 11 (the total gain of the respective gains of the LNA 13 and the VGA 14) and a gain control signal. The vertical and horizontal axes of the graph shown FIG. 6B indicate the gain (RF AGC Gain) of the entire RF unit 11 and a gain control signal (AGC_out), respectively, and the graph shows the gain characteristic of the RF unit 11. (a) through (g) shown in FIG. 6A correspond to (a) through (g), respectively, shown in FIG. 6B.

As shown in FIGS. 6A and 6B, firstly, when a waiting state transits to a packet receiving state, the AGC unit 18 performs steps 1 and 2 as the step-down process to change the gain control signal from (a) to (b) and to (c). In this case, the gain of the RF unit 11 decreases to ΔG1 and ΔG2, respectively.

Then, as shown in FIGS. 6A and 6B, when the LNA 13 stops between (c) and (d), the gain of the entire RF unit 11 decreases by ΔG1na. When the LNA 13 stops during StepDown1st, the AGC unit 18 is set so as not to compute an LNA switch compensation offset value.

Then, when a prescribed time elapses after the LNA 13 stops, the AGC unit 18 performs steps 3 and 4 again as the step-down process to change the gain control signal from (d) to (e) and to (f). In this case, the gain of the RF unit 11 decreases by ΔG3 and ΔG4, respectively.

Then, when the step-down process is completed, the AGC unit 18 continues to smoothly reduce the gain of the RF unit 11 up to a gain (Gt) for realizing a target signal level.

As described above, when the LNA 13 stops during StepDown1st, the AGC unit 18 performs a subsequent step-down process after a prescribed time elapses. Therefore, the gain of the RF unit 11 can be prevented from rapidly decreasing more than required.

(2) Only one step offset value can also be used in the step-down process and values obtained by increasing/decreasing the step offset value at a specific rate can also be used as the remaining step offset values. Specifically, for example, if the step offset value of step 1 out of steps 1 through 4 is “10” and the remaining step offset values are obtained by decreasing the step offset value by 20% each time, the step offset values of steps 2, 3 and 4 become “8”, “6.4” and “5.12”, respectively.

(3) Although in the above-mentioned preferred embodiment, the same value is used as the respective step offset values of StepDown1st and SteoDown2nd, a different value can also be set as each of the step offset values.

According to the present invention, normally the first gain change unit can control the gain of the variable gain amplifier and maintain the output level of the variable gain amplifier at a prescribed level corresponding to the reference level. Furthermore, if the output level of the variable gain amplifier exceeds the first threshold value accompanying the fluctuations of an input level or the like, the second gain change unit can force to reduce the gain of the variable gain amplifier by a prescribed value. Thus, the output level of the variable gain amplifier can be reduced below the first threshold value in a short time. In other words, the output level of the variable gain amplifier can be brought close to a prescribed value corresponding to the reference level in a short time. Since time needed to converge the output level of the variable gain amplifier on a prescribed value to be maintained from the first threshold value is almost constant, convergence time against the fluctuations of the input level or the like becomes almost constant.

1. A gain control circuit, comprising:
a detection unit for detecting the output level of a variable gain amplifier for amplifying and outputting an input signal;
a first gain change unit for adjusting the gain of the variable gain amplifier according to a difference between the output level detected by the detection unit and a predetermined reference level; and
a second gain change unit for forcing to reduce the gain of the variable gain amplifier if the output level detected by the detection unit exceeds a first predetermined threshold value.

2. The gain control circuit according to claim 1, wherein
said second gain change unit continues to stepwise reduce the gain of said variable gain amplifier at prescribed time intervals until the output level detected by said detection unit becomes below the first threshold value.

3. The gain control circuit according to claim 2, wherein
each amount of decrease used when stepwise reducing the gain of said variable gain amplifier can be set individually.

4. The gain control circuit according to claim 1, further comprising
a conversion unit for applying logarithmic conversion to the output level detected by said detection unit,
wherein
said first gain change unit adjusts the gain of said variable gain amplifier according to the difference between the log output level converted by said conversion unit and a predetermined reference level.

5. The gain control circuit according to claim 2, wherein
the change pattern of the gain of said variable gain amplifier can be arbitrarily set by modifying each amount of decrease and number of decrease used when stepwise reducing the gain of said variable gain amplifier.

6. The gain control circuit according to claim 1, further comprising, presuming that a pre-amplifier is provided before said variable gain amplifier
a switch control unit for stopping said pre-amplifier when the input level of said variable gain amplifier exceeds a predetermined second threshold value,
wherein
if the output level detected by said detection unit exceeds the predetermined first threshold value when said pre-amplifier stops, said second gain change unit forces to reduce the gain of said variable gain amplifier by a prescribed value.

7. The gain control circuit according to claim 1, further comprising, presuming that a pre-amplifier is provided before said variable gain amplifier
a switch control unit for stopping said pre-amplifier if the input level of said variable gain amplifier exceeds a predetermined second threshold value,
wherein
said second gain change unit adjusts the gain of said variable gain amplifier so as to compensate for gain decrease due to the stoppage of said pre-amplifier.

8. The gain control circuit according to claim 1, further comprising, presuming that a pre-amplifier is provided before said variable gain amplifier
a switch control unit for stopping said pre-amplifier if the input level of said variable gain amplifier exceeds a predetermined second threshold value,
wherein
said second gain change unit does not perform the compulsory decrease of the gain of said variable gain amplifier before a prescribed time elapses after said switch control unit stops said pre-amplifier.

9. An amplification device, comprising:
a variable gain amplifier for amplifying and outputting an input signal;
a detection unit for detecting the output of the variable gain amplifier;
a first gain change unit for adjusting the gain of the variable gain amplifier according to a difference between the output level detected by the detection unit and a predetermined reference level; and
a second gain change unit for forcing to reduce the gain of the variable gain amplifier by a prescribed value if the output level detected by the detection unit exceeds a predetermined first threshold value.
